(19) United States
(12) Patent Application Publication
(10) Pub. No.: US 2024/0105424 A1
(43) Pub. Date: Mar. 28, 2024

(54) PLASMA PROCESSING APPARATUS AND PLASMA PROCESSING METHOD

(71) Applicant: Tokyo Electron Limited, Tokyo (JP)

(72) Inventors: Takahiro TAKEUCHI, Miyagi (JP); Masahiko TAKAHASHI, Miyagi (JP); Ken KOBAYASHI, Miyagi (JP)

(73) Assignee: Tokyo Electron Limited, Tokyo (JP)

(21) Appl. No.: 18/534,224

(22) Filed: Dec. 8, 2023

Related U.S. Application Data
(63) Continuation of application No. PCT/JP2022/021356, filed on May 25, 2022.

(30) Foreign Application Priority Data
Jun. 8, 2021 (JP) 2021-095886

(51) Int. Cl. H01J 37/32

(52) U.S. Cl. CPC H01J 37/32146; H01J 37/32174; H01J 2237/334

(57) ABSTRACT

A first RF pulse signal includes a plurality of main cycles. Each main cycle includes first and second durations. The first duration includes a plurality of first sub cycles, and the second duration includes a plurality of second sub cycles. The first RF pulse signal has three or more different power levels in each of the plurality of first sub cycles and the plurality of second sub cycles. A second RF pulse signal including a plurality of main cycles. The second RF pulse signal has two or more different power levels in each of the plurality of first sub cycles and a zero power level in the second duration. A third RF pulse signal includes a plurality of main cycles. The third RF pulse signal has two or more different power levels in each of the plurality of first sub cycles and a zero power level in the second duration.

### CROSS-REFERENCE TO RELATED APPLICATIONS

This application is a Continuation of International Patent Application No. PCT/JP2022/021356, filed on May 25, 2022, which claims priority from Japanese Patent Application No. 2021-095886, filed on Jun. 8, 2021, all of each are incorporated herein in their entireties by reference.

### TECHNICAL FIELD

The present disclosure relates to a plasma processing apparatus and a plasma processing method.

### BACKGROUND

Japanese Patent Publication No. 2019-067503 discloses a plasma processing apparatus, which includes two RF power supplies, and supplies two- frequency RF power signals to an antenna above a chamber and a susceptor. One of the two RF power supplies a bias RF power with a frequency of, for example, 13 MHz to the susceptor. The antenna is provided above the chamber, and the other RF power supply supplies a plasma excitation RF power with a frequency of, for example, 27 MHz to the antenna.

U.S. Patent Application Publication No. 2020/0058470 discloses a plasma processing system including a source power (SP) coupling element and a bias power (BP) coupling element that are coupled to a plasma processing chamber. The SP coupling element is, for example, an antenna and is configured to supply a source power. The BP coupling element is, for example, an electrostatic chuck and is configured to supply a bias power.

### SUMMARY

According to an aspect of the present disclosure, a plasma processing apparatus includes: a plasma processing chamber; a substrate support disposed in the plasma processing chamber; an electrode disposed in the substrate support; a first RF generator that is coupled to the plasma processing chamber, and generates a first RF pulse signal including a plurality of main cycles, in which each main cycle includes a first duration and a second duration, the first duration includes a plurality of first sub cycles, the second duration includes a plurality of second sub cycles, and the first RF pulse signal has three or more different power levels in each of the plurality of first sub cycles and the plurality of second sub cycles; a second RF generator that is coupled to the electrode, and generates a second RF pulse signal including the plurality of main cycles, in which the second RF pulse signal has two or more different power levels in each of the plurality of first sub cycles and a zero power level in the second duration; and a third RF generator that is coupled to the electrode, and generates a third RF pulse signal including the plurality of main cycles, in which the third RF pulse signal has two or more different power levels in each of the plurality of first sub cycles and a zero power level in the second duration.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a configuration of a plasma processing system.

FIG. 2 is a vertical cross-sectional view schematically illustrating a configuration of a plasma processing apparatus.

FIG. 3 is a view illustrating examples of changes of radicals, ions, an electron temperature (e.g., a plasma electron temperature), ion energy, and by-products over time.

FIG. 4 is a view illustrating patterns of two RF power signals that are continuous waves, in Comparative Example 1.

FIG. 5 is a cross-sectional view illustrating pattern shapes after an etching in Comparative Example 1.

FIG. 6 is a view illustrating pulse patterns of two-frequency RF power pulses in Comparative Example 2.

FIG. 7 is a view illustrating the pulse patterns of the two-frequency RF power pulses in one period of a sub cycle in Comparative Example 2.

FIG. 8 is a cross-sectional view illustrating pattern shapes after an etching in Comparative Example 2.

FIG. 9 is a view illustrating pulse patterns of two-frequency RF power pulses according to a first embodiment.

FIG. 10 is a cross-sectional view illustrating pattern shapes after an etching according to the first embodiment.

FIG. 11 is a view illustrating pulse patterns of two-frequency RF power pulses according to a modification of the first embodiment.

FIG. 12 is a view illustrating pulse patterns of two-frequency RF power pulses according to a second embodiment.

FIG. 13 is a view illustrating the pulse patterns of the two-frequency RF power pulses in one period of a sub cycle according to the second embodiment.

FIG. 14 is a view illustrating pulse patterns of three-frequency RF power pulses according to a third embodiment.

FIG. 15 is a view illustrating the pulse patterns of the three-frequency RF power pulses in one period of a sub cycle according to the third embodiment.

FIGS. 16A and 16B are views illustrating a state where an etching target film is being etched, according to the third embodiment.

FIG. 17 is a view illustrating pulse patterns of three-frequency RF power pulses according to a fourth embodiment.

FIG. 18 is a view illustrating the pulse patterns of the three-frequency RF power pulses in one period of a sub cycle according to the fourth embodiment.

FIGS. 19A to 19C are views illustrating a state where an etching target film is being etched, according to the fourth embodiment.

FIG. 20 is a view illustrating pulse patterns of three-frequency RF power pulses in one period of a first sub cycle according to a modification of the fourth embodiment.

FIG. 21 is a view illustrating pulse patterns of three-frequency RF power pulses in one period of a first sub cycle according to another modification of the fourth embodiment.

FIG. 22 is a view illustrating pulse patterns of three-frequency RF power pulses in one period of a first sub cycle according to yet another modification of the fourth embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In a process of manufacturing semiconductor devices, a plasma processing such as an etching or deposition is performed on a semiconductor substrate (hereinafter, referred to as a “substrate”). In the plasma processing, a plasma is generated by exciting a processing gas, so that the substrate is processed with the generated plasma.

As a plasma source, for example, an inductively coupled plasma (ICP) may be used. The plasma processing apparatus disclosed in Japanese Patent Laid-Open Publication No. 2019-067503 is the inductively coupled plasma processing apparatus, which supplies a plasma excitation radio-frequency power to the antenna to generate a plasma from a processing gas, and concurrently, supplies a bias radio- frequency power to the susceptor to draw ions into the substrate. Then, a plasma processing is performed on the substrate with the generated plasma.

For example, when an etching is performed as the plasma processing, it is important to control the incidence angle of ions with respect to the etching target film on the substrate, thereby controlling pattern shapes after the etching. In this regard, U.S. Patent Application Publication No. 2020/0058470 discloses a plasma processing method using a plasma processing system, in which a source power includes a plurality of source power pulses, and a bias power includes a plurality of bias power pulses. Then, a plasma is generated by forming a pulse sequence that is a combination of the plurality of source power pulses and the plurality of bias power pulses. Specifically, in the pulse sequence, the source power pulses and the bias power pulses are combined alternately, for example, such that the pulses do not overlap with each other in time.

However, upon intensive studies, the inventors of the present disclosure have found that the plasma processing using the pulse sequence may not achieve desired pattern shapes after the plasma processing, e.g., after the etching. Especially, when sparse and dense patterns are present, it is necessary to improve the control of pattern shapes.

The technology of the present disclosure has been made in consideration of the circumstances above, and improves the process performance and the pattern shapes after a plasma processing, by using a plurality of radio-frequency pulse signals. Hereinafter, a plasma processing apparatus and a plasma processing method according to embodiments of the present disclosure will be described with reference to the drawings. In the descriptions and the drawings herein, components having substantially the same functional configuration will be denoted by the same reference numerals, and overlapping descriptions thereof will be omitted.

### Plasma Processing System

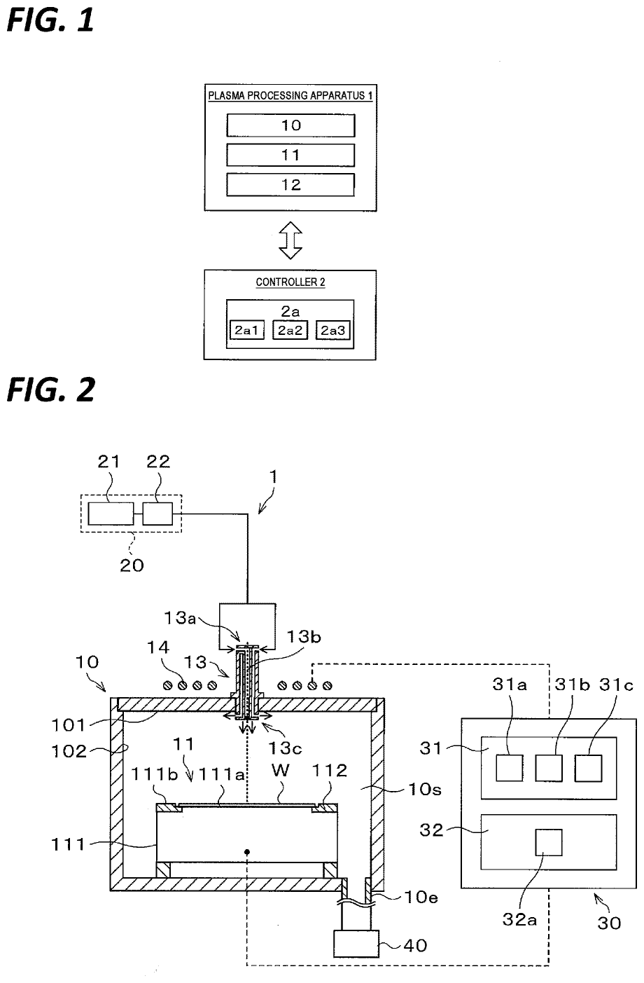

First, a plasma processing system according to an embodiment will be described using FIG. 1. FIG. 1 is a view schematically illustrating the configuration of the plasma processing system.

In an embodiment, the plasma processing system includes a plasma processing apparatus 1 and a controller 2. The plasma processing apparatus 1 is configured to supply three radio-frequency power pulses (e.g., three RF pulse signals) into a plasma processing chamber 10, thereby generating a plasma from a processing gas in the plasma processing chamber 10. The plasma processing apparatus 1 may be configured to supply two radio-frequency power pulses (e.g., two RF pulse signals) into the plasma processing chamber 10, thereby generating a plasma from a processing gas in the plasma processing chamber 10. Then, the plasma processing apparatus 1 processes a substrate by exposing the substrate to the generated plasma.

The plasma processing apparatus 1 includes the plasma processing chamber 10, a substrate support 11, and a plasma generator 12. The plasma processing chamber 10 has a plasma processing space. Further, the plasma processing chamber 10 includes at least one gas supply port for supplying at least one processing gas into the plasma processing space, and at least one gas discharge port for discharging a gas from the plasma processing space. The gas supply port is connected to a gas supply 20 to be described later, and the gas discharge port is connected to an exhaust system 40 to be described later. The substrate support 11 is disposed in the plasma processing space, and has a substrate supporting surface for supporting a substrate thereon.

The plasma generator 12 is configured to generate a plasma from at least one processing gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Further, various types of plasma generators may be used, including an alternating current (AC) plasma generator and a direct current (DC) plasma generator. In an embodiment, an AC signal (e.g., an AC power) used in the AC plasma generator has a frequency in the range of 100 kHz to 10 GHz. Accordingly, the AC signal includes a radio frequency (RF) signal and a microwave signal. In an embodiment, the RF signal has a frequency in the range of 100 kHz to 150 MHz.

The controller 2 processes computer-executable commands for causing the plasma processing apparatus 1 to perform various processes described herein. The controller 2 may be configured to control each component of the plasma processing apparatus 1 to perform the various processes described herein. In an embodiment, a portion of the controller 2 or the entire controller 2 may be included in the plasma processing apparatus 1. The controller 2 may include, for example, a computer 2a. The computer 2a may include, for example, a processor (e.g., a central processing unit; CPU) 2a1, a storage 2a2, and a communication interface 2a3. The processor 2a1 may be configured to perform various control operations based on programs stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Hereinafter, descriptions will be made on an example of a configuration of an inductively coupled plasma processing apparatus, which is an example of the plasma processing apparatus 1, using FIG. 2. FIG. 2 is a vertical cross-sectional view schematically illustrating the configuration of the plasma processing apparatus 1. While the plasma processing apparatus 1 performs a plasma processing on the substrate (e.g., a wafer) W, the substrate W subjected to the plasma processing is not limited to the wafer.

The inductively coupled plasma processing apparatus 1 includes the plasma processing chamber 10, the gas supply 20, a power supply 30, and an exhaust system 40. The plasma processing chamber 10 includes a dielectric window 101. Further, the plasma processing apparatus 1 includes the substrate support 11, a gas introduction unit, and an antenna 14. The substrate support 11 is disposed inside the plasma processing chamber 10. The antenna 14 is disposed on or above the plasma processing chamber 10 (i.e., on or above the dielectric window 101). The plasma processing chamber 10 has a plasma processing space 10s defined by the dielectric window 101, the side wall 102 of the plasma processing chamber 10, and the substrate support 11.

The substrate support 11 includes a main body 111 and a ring assembly 112. The main body 111 includes a central region 111a for supporting the substrate W (e.g., the substrate supporting surface) and an annular region 111b for supporting the ring assembly 112 (e.g., the ring supporting surface). The annular region 111b of the main body 111 surrounds the central region 111a of the main body 111 in a plan view. The substrate W is placed on the central region 111a of the main body 111, and the ring assembly 112 is disposed on the annular region 111b of the main body 111 to surround the substrate W placed on the central region 111a of the main body 111. In an embodiment, the main body 111 includes a base and an electrostatic chuck. The base includes a conductive member. The conductive member of the base functions as a lower electrode. The lower electrode may be disposed inside the electrostatic chuck. The electrostatic chuck includes a ceramic plate and an electrostatic electrode disposed inside the ceramic plate. The electrostatic chuck is disposed on the base. The upper surface of the electrostatic chuck serves as the substrate supporting surface 111a. The ring assembly 112 includes one or a plurality of annular members. At least one of the one or more annular members is an edge ring. Although not illustrated, the substrate support 11 may include a temperature adjustment module configured to adjust at least one of the electrostatic chuck, the ring assembly 112, and the substrate W to a target temperature. The temperature adjustment module may include a heater, a heat transfer medium, a flow path, or a combination thereof. A heat transfer fluid such as brine or a gas flows through the flow path. The substrate support 11 may include a heat transfer gas supply configured to supply a heat transfer gas to the space between the rear surface of the substrate W and the substrate supporting surface 111a.

The gas introduction unit is configured to introduce at least one processing gas from the gas supply 20 into the plasma processing space 10s. In an embodiment, the gas introduction unit includes a center gas injector (CGI) 13. The center gas injector 13 is disposed above the substrate support 11, and provided at a central opening formed in the dielectric window 101. The center gas injector 13 includes at least one gas supply port 13a, at least one gas flow path 13b, and at least one gas introduction port 13c. A processing gas supplied to the gas supply port 13a passes through the gas flow path 13b and is introduced into the plasma processing space 10s from the gas introduction port 13c. In addition to or instead of the center gas injector 13, the gas introduction unit may include one or more side gas injectors (SGI) provided in one or more openings formed in the side wall 102.

The gas supply 20 may include at least one gas source 21 and at least one flow controller 22. In an embodiment, the gas supply 20 is configured to supply at least one processing gas from its corresponding gas source 21 to the gas introduction unit via its corresponding flow controller 22. Each flow controller 22 may include, for example, a mass flow controller or a pressure-controlled flow controller. The gas supply 20 may further include at least one flow modulation device that modulates or pulses the flow of at least one processing gas.

The power supply 30 includes an RF power supply 31 coupled to the plasma processing chamber 10 via at least one impedance matching circuit. The RF power supply 31 is configured to supply three RF signals (e.g., RF powers) to the conductive member of the substrate support 11 and the antenna 14. Thus, a plasma is formed from at least one processing gas supplied into the plasma processing space 10s. Accordingly, the RF power supply 31 may function as at least a portion of the plasma generator 12. Further, by supplying a bias RF signal to the conductive member of the substrate support 11, a bias potential is generated in the substrate W, so that ions in the formed plasma may be drawn into the substrate W.

In an embodiment, the RF power supply 31 includes a first RF generator 31a, a second RF generator 31b, and a third RF generator 31c. The first RF generator 31a is coupled to the antenna 14, and the second and third RF generators 31b and 31c are coupled to the conductive member.

The first RF generator 31a is coupled to the antenna 14 via at least one impedance matching circuit, and configured to generate a first RF pulse signal (e.g., a pulsed signal having HF power) for plasma generation. The generated first RF pulse signal is supplied to the antenna 14. In an embodiment, the first RF pulse signal has a first frequency in the range of 13 MHz to 150 MHz. In an embodiment, the first RF pulse signal has a first frequency in the range of 13 MHz to 100 MHz. In an embodiment, the first RF pulse signal has a first frequency in the range of 20 MHz to 60 MHz. The first RF pulse signal includes a plurality of pulse cycles, specifically, a plurality of main cycles to be described later. Each main cycle includes first and second durations. The first duration includes a plurality of first sub cycles, and the second duration includes a plurality of second sub cycles. The first sub cycles have a first time duration, and the second sub cycles have a second time duration. In an embodiment, the first time duration is the same as the second time duration. In this case, each main cycle includes a plurality of sub cycles. The first RF pulse signal has at least three power levels, which is each equal to or more than 0. Thus, the first RF pulse signal may have power levels of High/Middle/Low, which are greater than zero. The first RF pulse signal may have power levels of High/Low and a zero power level (OFF). In an embodiment, the first RF pulse signal has three or more different power levels in each of the plurality of first sub cycles and the plurality of second sub cycles.

The second RF generator 31b is coupled to the lower electrode in the substrate support 11 via at least one impedance matching circuit, and configured to generate a second RF pulse signal (e.g., a pulsed signal having LF1 power). The generated second RF pulse signal is supplied to the lower electrode in the substrate support 11. The second RF pulse signal has a second frequency. The second frequency may be the same as or different from the first frequency. In an embodiment, the second frequency is less than the first frequency. In an embodiment, the second RF pulse signal has the second frequency in the range of 100 kHz to 60 MHz. In an embodiment, the second RF pulse signal has the second frequency less than 1 MHz (a kilohertz RF frequency). In an embodiment, the second RF pulse signal has the second frequency in the range of 1 MHz to 15 MHz. In an embodiment, the second RF pulse signal has the second frequency in the range of 100 kHz to 2 MHz. The second RF pulse signal includes a plurality of pulse cycles. The second RF pulse signal has at least two power levels, which are each equal to or more than zero. Thus, the second RF pulse signal may have power levels of High/Low, which are greater than zero. The second RF pulse signal may have a power level greater than zero and a zero power level, i.e., ON/OFF signals. In an embodiment, the second RF pulse signal has two or more different power levels in each of the plurality of first sub cycles, and a zero power level in the second duration.

The third RF generator 31c is coupled to the lower electrode in the substrate support 11 via at least one impedance matching circuit, and configured to generate a third RF pulse signal (e.g., a pulsed signal having LF2 power). The generated third RF pulse signal is supplied to the lower electrode in the substrate support 11. In an embodiment, the third RF pulse signal has a frequency less than the second RF pulse signal. In an embodiment, the third RF pulse signal has a third frequency in the range of 100 kHz to 4 MHz. In an embodiment, the third RF pulse signal has the third frequency in the range of 100 kHz to 2 MHz. In an embodiment, the third RF pulse signal has the third frequency less than 1 MHz (e.g., a kilohertz RF frequency). The third RF pulse signal includes a plurality of pulse cycles. The third RF pulse signal has at least two power levels, which are each equal to or more than zero. Thus, the third RF pulse signal may have power levels of High/Low, which are more than zero. Further, the third RF pulse signal may have a power level greater than zero and a zero power level, i.e., ON/OFF signals. The third RF pulse signal has two or more different power levels in each of the plurality of first sub cycles, and the zero power level in the second duration.

In this way, the first, second, and third RF pulse signals are pulsed. The second and third RF pulse signals are pulsed between the ON and OFF states or between two or more different ON states (High/Low). The first RF pulse signal is pulsed among two or more different ON states (High/Low) and the OFF state, or among three or more different ON states (High/Middle/Low). The first RF pulse signal may be pulsed between the ON and OFF states or between two different ON states (High/Low).

The controller 2 outputs a control signal for instructing each of the first, second, and third RF generators 31a, 31b, and 31c to supply each pulse signal. Accordingly, the first, second, and third RF pulse signals each including a plurality of pulse cycles (e.g., the main cycles and the sub cycles) are supplied at predetermined timings, so that a plasma is generated from a processing gas in the plasma processing chamber 10. Then, a plasma processing is performed by exposing the generated plasma to the substrate. As a result, the process efficacy may be improved, so that a plasma processing may be performed with a high precision. The timings for controlling the ON/OFF states or the zero or more power levels of the first, second, and third RF pulse signals by the controller 2 will be described later.

The power supply 30 may further include a DC power supply 32 coupled to the plasma processing chamber 10. The DC power supply 32 includes a bias DC generator 32a. In an embodiment, the bias DC generator 32a is connected to the conductive member of the substrate support 11, and configured to generate a bias DC signal. The generated bias DC signal is applied to the conductive member of the substrate support 11. In an embodiment, the bias DC signal may be applied to another electrode such as an electrode inside the electrostatic chuck. In various embodiments, the bias DC signal may be pulsed. The bias DC generator 32a may be provided in addition to the RF power supply 31, or may be provided instead of the second and third RF generators 31b and 31c.

The antenna 14 includes one or a plurality of coils. In an embodiment, the antenna 14 may include an outer coil and an inner coil, which are arranged coaxially. In this case, the RF power supply 31 may be connected to both or either one of the outer coil and the inner coil. In the former case, the same RF generator may be connected to both the outer coil and the inner coil, or separate RF generators may be connected to the outer coil and the inner coil, respectively.

The exhaust system 40 may be connected to a gas discharge port 10e formed at, for example, the bottom of the plasma processing chamber 10. The exhaust system 40 may include a pressure regulating valve and a vacuum pump. The pressure in the plasma processing space 10s is regulated by the pressure regulating valve. The vacuum pump may include a turbo molecular pump, a dry pump, or a combination thereof.

### Pulsed Signals

Next, a pulsed signal of each RF power will be described. For example, when the plasma processing is a process of etching a deep hole with a high aspect ratio, the incidence angle of ions may be controlled to be vertical or the mask selectivity may be increased, by using the pulse signals of the HF power, the LF1 power, and the LF2 power.

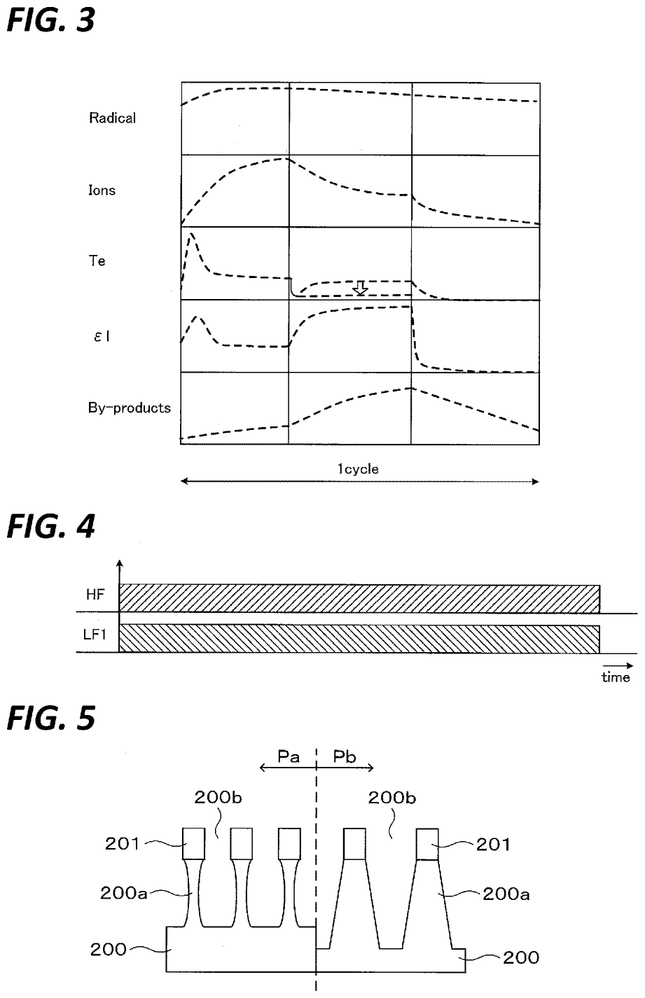

FIG. 3 is a view illustrating examples of changes of radicals, ions, an electron temperature (e.g., a plasma electron temperature), an ion energy, and by-products over time. The horizontal axis of FIG. 3 represents an elapsed time (e.g., one cycle) after the supply of each RF power is stopped (OFF). The vertical axis of FIG. 3 represents the states of the radicals (Radical), ions (Ions), electron temperature (Te), ion energy (εl), and by-products (By-products) at each time during the OFF time.

As illustrated in FIG. 3, the radicals change gradually after the RF power is turned OFF, whereas the ions and the electron temperature change faster than the radicals after the RF power is turned OFF. The pulsed signals of the HF power and LF power (e.g., the LF1 power and the LF2 power) are controlled in consideration of, for example, the decline of radicals, ions, and electron temperature or the change of energy, in the plasma.

As for an example of the pulse signal of the LF power supplied after the HF power is turned OFF, there is a control to turn OFF the LF power during an initial time when the electron temperature is high, and turn ON the LF power after the electron temperature declines. In this case, ions remaining in the plasma may be efficiently drawn into the substrate by using the LF power during the time when the electron temperature is low.

As for another example of the pulse signal of the LF power supplied after the HF power is turned OFF, there is a control to control the LF power during a time when the electron temperature does not substantially change, by using the ion energy as a plasma parameter. As a result, by controlling the ion energy, the incidence angle of ions may be controlled to be further vertical.

As described above, the timings for turning the HF power and the LF power into the ON/OFF states are controlled according to the movements of plasma parameters such as the radicals, ions, electron temperature, ion energy, and by- products. As a result, the process performance may be improved. Hereinafter, the timing for supplying the pulsed signal of each RF power will be described. The timing for supplying the pulsed signal of each RF power is controlled by the controller 2.

Hereinafter, descriptions will be made on a case where the plasma processing is an etching process, and an etching target film is silicon. However, the plasma processing to which the present disclosure is applied is not limited to the etching process, but may be, for example, a film forming process. The etching target film is not also limited to silicon, but the present disclosure may be applied to other film types.

### Two-Frequency Pulse Signals

The pulse patterns of two-frequency RF power pulses according to a first embodiment will be described using Comparative Examples 1 and 2. In the first embodiment and Comparative Examples 1 and 2, the two-frequency (two frequencies) RF power signals are the HF power (e.g., a source power) and the LF1 power (e.g., a bias power).

### Comparative Example 1

FIG. 4 is a view illustrating patterns of two RF power signals, which are continuous waves, in Comparative Example 1. In FIG. 4, the horizontal axis represents time, and the vertical axis represents the ON/OFF states of the HF power and the LF1 power. FIG. 5 illustrates results obtained when the etching target film is etched by executing Comparative Example 1. In FIG. 5, the left side of the dashed line represents a dense region of patterns in which an etching target film 200 is etched through a mask 201 (dense patterns Pa). The right side of the dashed line represents a sparse region of patterns in which the etching target film 200 is etched through the mask 201 (sparse patterns Pb).

As illustrated in FIG. 5, in the dense patterns Pa of Comparative Example 1, the amount of ions reaching the bottom of a recess 200b between protrusions 200a in the etching target film 200 is small, and the protrusions 200a are excessively etched. Meanwhile, in the sparse patterns Pb, a deeper etching may be performed than in the dense patterns Pa, but each protrusion 200a has a tapered shape that becomes thicker downward. Thus, in Comparative Example 1, the sparse and dense pattern shapes after the etching may not be appropriately controlled.

### Comparative Example 2

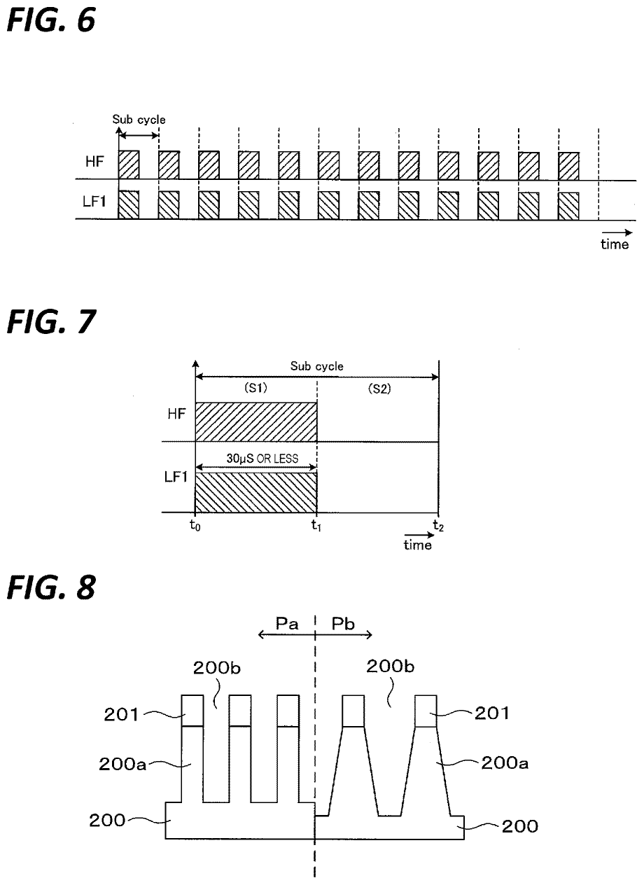

FIG. 6 is a view illustrating pulse patterns of two-frequency RF power pulses in Comparative Example 2. FIG. 7 is a view illustrating the pulse patterns of the two-frequency RF power pulses in one period of a sub cycle in Comparative Example 2. In FIGS. 6 and 7, the horizontal axis represents time, and the vertical axis represents the ON/OFF states of the HF power and the LF1 power.

The pulse signal of each of the HF and LF1 powers includes a plurality of pulse cycles. Hereinafter, the pulse cycles will be referred to as sub cycles that conform to the terms used in the first embodiment to be described later. Each sub cycle includes a first sub duration S1 and a second sub duration S2, and the control of the pulse signals of each of the HF power and the LF1 power is repeated with the sub cycle as one period.

In the control of the two-frequency RF power pulses in Comparison Example 2, the ON state of the HF power and the ON state of the LF1 power overlap with each other in time. That is, while the HF power is at the ON state, the LF1 power is at the ON state, and while the HF power is at the OFF state, the LF1 power is at the OFF state.

The first RF generator 31a is configured to generate a first RF pulse signal (e.g., the HF power), and in Comparison Example 2, the first RF pulse signal has two power levels (ON/OFF). For example, the first RF pulse signal may have a frequency of 27 MHz.

The second RF generator 31b is configured to generate a second RF pulse signal (e.g., the LF1 power), and in Comparison Example 2, the second RF pulse signal has two power levels (ON/OFF). The frequency of the second RF pulse signal is less than the frequency of the first RF pulse signal. For example, the second RF pulse signal has a frequency of 13 MHz.

In the first sub duration S1 of FIG. 7, the HF power and the LF1 power are maintained in the ON state. That is, the HF power and the LF1 power transition to the ON state at a timing t0, and transition to the OFF state at a timing t1. As a result, during the time from the timing tO to the timing t1, a plasma containing radicals and ions is generated by the supply of the HF power, and the flux of ions (e.g., the amount of ions) reaching the bottom of a recess being etched is controlled by the supply of the LF1 power, so that the etching is accelerated.

The HF power and the LF1 power transition to the OFF state at the timing t1 after the first sub duration S1, and are maintained at the OFF state in the second sub duration S2. Since the HF power is at the OFF state in the second sub duration S2, the radicals, ions, and electron temperature decline with their respective time constants as in the example illustrated in FIG. 3. Further, since the HF power and the LF1 power are at the OFF state in the second sub duration S2, by-products are exhausted.

At the timing t2 after the second sub duration S2 elapses, the second sub duration S2 returns to the first sub duration S1, and at the timing t0, the HF power and the LF1 power transition to the ON state again. Then, the control of the pulse signal of each of the HF power and the LF1 power is repeated with the first and second sub durations S1 and S2 as one period. One period of the sub cycle is 1 kHz to 20 kHz. The plurality of sub cycles have the same time duration, and each sub cycle has a time duration of 50 μs to 100 μs. That is, one period of the sub cycle is 50 μs to 100 μs.

In Comparison Example 2, the second RF generator 31b is configured to synchronize the timing for changing the power level of the second RF pulse signal with the timing for changing the power level of the first RF pulse signal.

The first sub duration S1 is set to 30 μs or less. The subsequent second sub duration S2 is set to an arbitrary time, which may be longer than 30 μs. That is, in this example, the HF power and the LF1 power are maintained at the ON state for the time of 30 μs or less in the first sub duration S1 and at the OFF state for an arbitrary time in the second sub duration S2, so that the ON/OFF are repeated in this manner The supply time of the LF1 power in one period is set to 30 μs or less, so that the ion incidence angle may be controlled to be vertical, which may implement the highly anisotropic etching.

The power level of the HF power in the first sub duration S1 is an example of a first power level. The power level of the HF power in the second sub duration S2 is an example of a second power level, and is a zero power level. The power level of the LF1 power in the first sub duration S1 is an example of a third power level. The power level of the LF1 power in the second sub duration S2 is an example of a fourth power level, and is a zero power level.

In Comparative Example 2, as described above, the etching target film is etched using a plasma in the first sub duration S1, and by-products are exhausted in the second sub duration S2. As compared to Comparative Example 1, the pattern shapes after the etching may be improved.

However, when the etching target film is etched by executing Comparative Example 2, the protrusions 200a are formed in a desired shape, but the etching target film 200 is not etched to a desired depth, in the dense patterns Pa illustrated in FIG. 8. Meanwhile, in the sparse patterns Pb, the etching may be performed deeper than in the dense patterns Pa, but each protrusion 200a has a tapered shape that becomes thicker downward. Thus, in Comparative Example 2, the sparse and dense pattern shapes after the etching may not be appropriately controlled. Upon intensive studies, the inventors of the present disclosure have found that the pattern shapes cannot be controlled because the time of the second sub duration S2 is short, and by-products are not sufficiently exhausted and remain in the recess 200b.

### First Embodiment

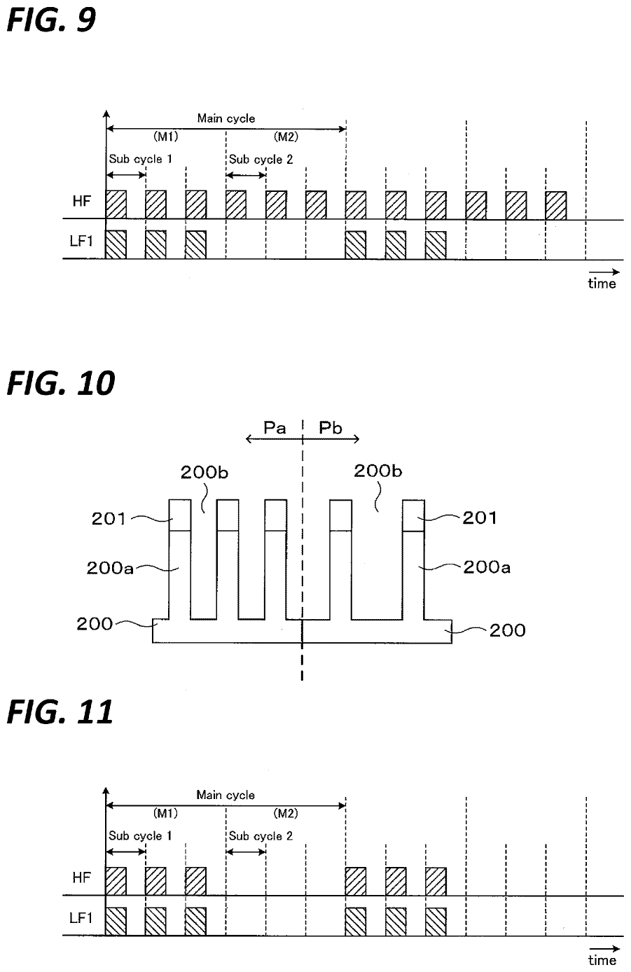

FIG. 9 is a view illustrating pulse patterns of two-frequency RF power pulses according to the first embodiment. In FIG. 9, the horizontal axis represents time, and the vertical axis represents the ON/OFF states of the HF power and the LF1 power.

The pulse signal of each of the HF power and the LF1 power includes a plurality of pulse cycles, specifically, a plurality of main cycles as described later, and each main cycle includes a plurality of sub cycles. The main cycle includes a first duration M1 and a second duration M2. One period of the main cycle is 10 Hz to 200 Hz. The first duration M1 includes a plurality of first sub cycles, and the second duration M2 includes a plurality of second sub cycles. The duration of each of the first and second sub cycles is the same as the duration of the sub cycle in Comparative Example 2, and one period of each of the first and second sub cycles is 1 kHz to 20 kHz. The control of the pulse signal of each of the HF power and the LF1 power is repeated with the main cycle as one period.

In each of the first sub cycles of the first duration M1 of FIG. 9, the pulse signal of each of the HF power and the LF1 power is controlled in the same manner as in the sub cycle of Comparison Example 2. That is, in the first sub cycle, the HF power and the LF1 power are maintained at the ON state for the first sub duration S1, and at the OFF state for the second sub duration S2. Then, the etching target film is etched using a plasma containing radicals and ions in the first sub duration S1, and by-products are exhausted in the second sub duration S2. In the first duration M1 , the first sub cycle is repeated so that the etching of the etching target film is progressed.

Subsequently, in each second sub cycle of the second duration M2, the pulse signal of the HF power is controlled in the same manner as in the first duration M1. That is, the HF power is maintained at the ON state in the first sub duration S1, and at the OFF state in the second sub duration S2. The HF power in the first sub duration S1 is the same as the HF power turned ON in the first duration M1. Meanwhile, in each second sub cycle, the LF1 power is not supplied in both the first and second sub durations S1 and S2. That is, the power level of the LF1 power pulse signal (e.g., the second RF pulse signal) is a zero power level. In this case, since the LF1 power is at the OFF state in the second duration M2, by-products are exhausted. Further, the second duration M2 is preset to a time, which is sufficiently long and prevents by-products from adhering to the substrate W.

When the etching target film is etched by executing the first embodiment, the protrusions 200a are formed in a desired shape in both the dense pattern Pa and the sparse pattern Pb as illustrated in FIG. 10, so that the etching target film 200 may be etched to a desired depth. This is because the LF1 power is turned OFF in the second duration M2 so that by-products are sufficiently exhausted and do not remain That is, by resolving the cause that impedes the shape improvement in Comparative Example 2, the first embodiment may appropriately control the sparse and dense pattern shapes after the etching.

Thus, the first RF pulse signal HF has two or more different power levels (e.g., ON/OFF) in each of the plurality of first sub cycles (Sub cycles 1) and the plurality of second sub cycles (Sub cycles 2). The plurality of first sub cycles are included in the first duration M1. The plurality of second sub cycles are included in the second duration M2. Each first sub cycle has a first time duration, and each second sub cycle has a second time duration. In an embodiment, the first time duration is the same as the second time duration. In this case, each main cycle includes a plurality of sub cycles (Sub cycles 1+Sub cycles 2). The first RF pulse signal HF has a first pulse pattern in each of the plurality of first sub cycles and a second pulse pattern in each of the plurality of second sub cycles. In an embodiment, the first pulse pattern is the same as the second pulse pattern. Further, the second RF pulse signal LF1 has two or more different power levels (e.g., ON/OFF) in each of the plurality of first sub cycles of the first duration M1 , and a zero power level in the second duration M2. That is, the second RF pulse signal LF1 is maintained at a zero power level in the second duration M2.

### Modification of First Embodiment

As a modification of the first embodiment, the HF power may not be supplied and may be turned OFF in the second duration M2, as illustrated in FIG. 11. In this case, in the second duration M2, the etching of the etching target film is not progressed, and by-products are more reliably exhausted.

### Second Embodiment

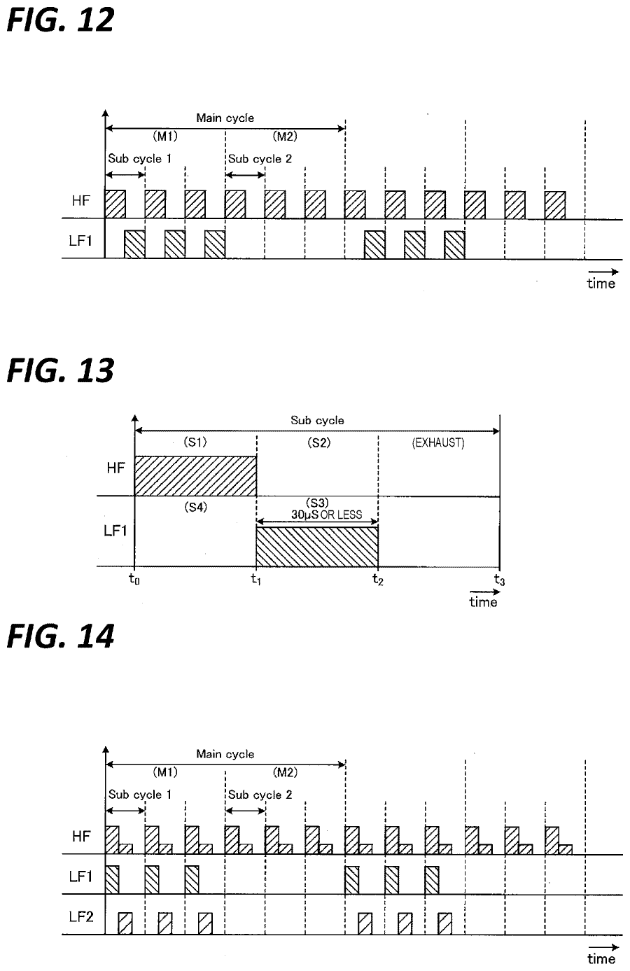

FIG. 12 is a view illustrating pulse patterns of two-frequency RF power pulses according to a second embodiment. FIG. 13 is a view illustrating the pulse patterns of the two-frequency RF power pulses in one period of a sub cycle according to the second embodiment. In FIGS. 12 and 13, the horizontal axis represents time, and the vertical axis represents the ON/OFF states of the HF power and the LF1 power.

As illustrated in FIG. 12, in the second embodiment, the main cycle includes a first duration M1 including a plurality of first sub cycles and a second duration M2 including a plurality of second sub cycles as in the first embodiment. One period of the main cycle is 10 Hz to 200 Hz. As illustrated in FIG. 13, each sub cycle of the HF power (e.g., each of first and second sub cycles) includes a first sub duration S1 and a second sub duration S2, and has the first and second sub durations S1 and S2 and an exhaust duration as one period. Each first sub cycle of the LF1 power in the first duration M1 includes a third sub duration S3 and a fourth sub duration S4, and has the third and fourth sub durations S3 and S4 and an exhaust duration as one period. The LF1 power is not supplied in each second sub cycle of the second duration M2. One cycle of each of the first and second sub cycles is 1 kHz to 20 kHz. The control of the pulse signal of each of the HF power and the LF1 power is repeated with the main cycle as one period.

The first RF generator 31a is configured to generate a first RF pulse signal (e.g., the HF power), and in the second embodiment, the first RF pulse signal has two power levels (e.g., ON/OFF). For example, the first RF pulse signal may have a frequency of 27 MHz.

The second RF generator 31b is configured to generate a second RF pulse signal (e.g., the LF1 power), and in the second embodiment, the first RF pulse signal has two power levels (e.g., ON/OFF). For example, the second RF pulse signal has a frequency of 13 MHz.

In each first sub cycle of the first duration M1, the ON state of the HF power and the ON state of the LF1 power do not overlap with each other in time as illustrated in FIG. 13. For example, the first RF pulse signal has a first power level in the first sub duration S1, and a second power level in the second sub duration S2. The first power level is the ON state, and the second power level is the OFF state. That is, the second power level is a zero power level. The second RF pulse signal has a third power level in the third sub duration S3, and a fourth power level in the fourth sub duration S4. The third power level is the ON state, and the fourth power level is the OFF state. That is, the fourth power level is a zero power level. The first power level may be High, and the second power level may be Low. Further, the third power level may be High, and the fourth power level may be Low.

In the first sub duration S1 of FIG. 13, the HF power is maintained at the ON state, and in the fourth sub duration S4 coincident in time with the first sub duration S1, the LF1 power is maintained at the OFF state. As a result, during the time from the timing t0 to the timing t1, a plasma containing radicals and ions is generated by the supply of the HF power.

At the timing t1, the HF power transitions to the OFF state, and the LF1 power transitions to the ON state, so that the HF power is maintained at the OFF state in the second sub duration S2, and the LF1 power is maintained at the ON state in the third sub duration S3 coincident in time with the second sub duration S2. Since the HF power is at the OFF state in the second sub duration S2, the radicals, ions, and electron temperature decline with their respective time constants as in the example illustrated in FIG. 3. By the supply of the LF1 power in the third sub duration S3, the flux of ions (e.g., the amount of ions) reaching the bottom of a recess being etched is controlled, so that the etching is accelerated.

At the timing t2, the HF power is maintained at the OFF state, and the LF1 power transitions to the OFF state. Since the HF power and the LF1 power are at the OFF state in the exhaust duration after the second and third sub durations S2 and S3, by-products are exhausted.

At a timing t3, one period ends, and the first sub duration S1 of the next period begins. Then, at the timing t0 of the next period, the HF power transitions to the ON state again, and the LF1 power is maintained at the OFF state in the fourth sub duration S4. That is, the first sub cycle of the HF power is repeated with the first and second sub durations S1 and S2, and the exhaust duration as one period. Further, the first sub cycle of the LF1 power is repeated with the fourth and third sub durations S4 and S3, and the exhaust duration as one period. One period of the first sub cycle is 1 kHz to 20 kHz. The plurality of first sub cycles have the same time duration, and each first sub cycle has a time duration of 50 μs to 1,000 μs. That is, one period of the first sub cycle is 50 μs to 1,000 μs.

The third sub duration S3 does not overlap in time with the first sub duration S1. That is, the second RF generator 31b offsets the timing for changing the power level of the second RF pulse signal with respect to the timing for changing the power level of the first RF pulse signal, so that the ON state of the HF power and the ON state of the LF1 power do not overlap with each other in time.

The third sub duration S3 is set to 30 μs or less. The first, second, and fourth sub durations S1, S2, and S4 are set to arbitrary times, which may be longer than 30 μs. That is, in this example, the LF1 power is maintained at the ON state for the time of 30 μs or less in the third sub duration S3, and at the OFF state for the arbitrary times of the fourth sub duration S4 and the exhaust duration, so that the ON/OFF are repeated in this manner The supply time of the LF1 power in one period is set to 30 μs or less, so that the ion incidence angle may be controlled to be vertical, which may implement the highly anisotropic etching.

The power level of the HF power in the first sub duration S1 is an example of a first power level, and the power level of the HF power in the second sub duration S2 is an example of a second power level. The power level of the LF1 power in the third sub duration S3 is an example of a third power level, and the power level of the LF1 power in the fourth sub duration S4 is an example of a fourth power level.

Subsequently, in each second sub cycle of the second duration M2, the pulse signal of the HF power is controlled in the same manner as in the first duration M1. Meanwhile, in each second sub cycle, the LF1 power is not supplied in both the third and fourth sub durations S3 and S4. That is, the power level of the LF1 power pulse signal (e.g., the second RF pulse signal) is a zero power level. In this case, since the LF1 power is at the OFF state in the second duration M2, by-products are exhausted. Further, the second duration M2 is preset to a time, which is sufficiently long and prevents by-products from adhering to the substrate W.

### Three-Frequency Pulse Signals

Descriptions will be made on pulse patterns of three-frequency RF power pulses according to third and fourth embodiments. In the third and fourth embodiments, the three-frequency RF power signals are an HF power (e.g., a source power), an LF1 power (e.g., a bias power), and an LF2 power (e.g., a bias power). The pulse signal of each of the HF power, the LF1 power, and the LF2 power includes a plurality of pulse cycles, specifically, a plurality of main cycles, and each main cycle includes a plurality of sub cycles.

### Third Embodiment

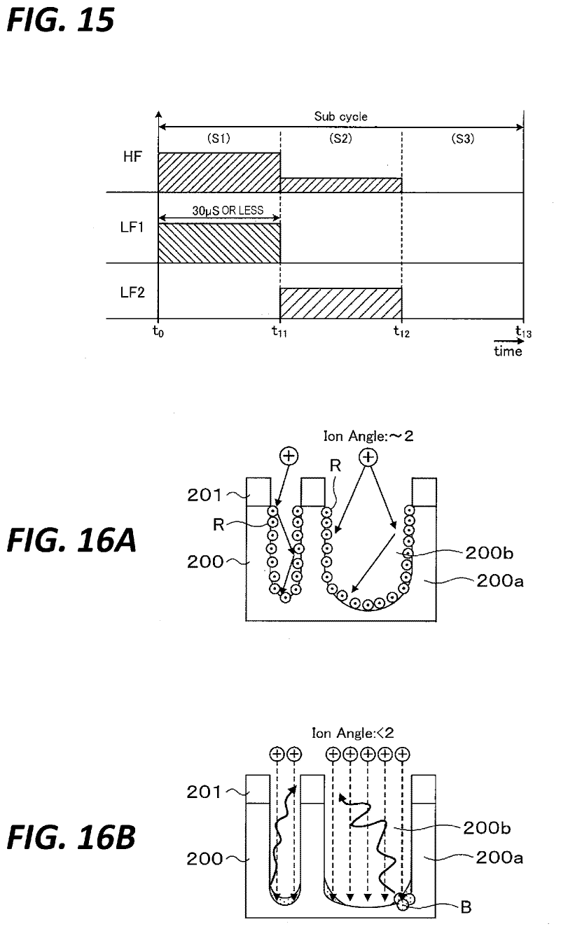

FIG. 14 is a view illustrating the pulse patterns of the three-frequency RF power pulses according to the third embodiment. FIG. 15 is a view illustrating the pulse patterns of the three-frequency RF power pulses in one period of a sub cycle according to the third embodiment. In FIGS. 14 and 15, the horizontal axis represents time, and the vertical axis represents the ON/OFF states of the HF power, the LF1 power, the LF2 power.

As illustrated in FIG. 14, in the third embodiment, the main cycle includes a first duration M1 including a plurality of first sub cycles and a second duration M2 including a plurality of second sub cycles, as in the first and second embodiments. One period of the main cycle is 10 Hz to 200 Hz. As illustrated in FIG. 15, each first sub cycle of the first duration M1 has the first to third sub durations S1 to S3 as one period. One period of the first sub cycle is 1 kHz to 20 kHz. Then, the control of the pulse signal of each of the HF power, the LF1 power, and the LF2 power is repeated with the main cycle as one period.

The first RF generator 31a is configured to generate a first RF pulse signal (e.g., the HF power), and in the third embodiment, the first RF pulse signal has three power levels (e.g., High/Low/OFF). These power levels may be set and changed arbitrarily according to a target process. For example, the first RF pulse signal may have a frequency of 27 MHz.

The second RF generator 31b is configured to generate a second RF pulse signal (e.g., the LF1 power), and in the third embodiment, the second RF pulse signal has two power levels (e.g., ON/OFF). That is, the second RF pulse signal has two or more power levels, which include a zero power level. The frequency of the second RF pulse signal is less than the frequency of the first RF pulse signal. For example, the second RF pulse signal has a frequency of 13 MHz.

The third RF generator 31c is configured to generate a third RF pulse signal (e.g., the LF2 power), and in the third embodiment, the third RF pulse signal has two power levels (e.g., ON/OFF). That is, the third RF pulse signal has two or more power levels, which include a zero power level. The frequency of the third RF pulse signal is less than the frequency of the second RF pulse signal. For example, the third RF pulse signal has a frequency of 1.2 MHz.

In each first sub cycle of the first duration M1, the ON state of the LF1 power and the ON state of the LF2 power do not overlap with each other in time as illustrated in FIG. 15. While the LF1 power is at the ON state, the LF2 power is at the OFF state, and while the LF1 power is at the OFF state, the LF2 power is at the ON state. The ON state of the HF power and the ON state of the LF1 power, and the ON state of the HF power and the ON state of the LF2 power may or may not overlap with each other in time.

For example, the first RF pulse signal has a first power level in the first sub duration S1, a second power level in the second sub duration S2, and a third power level in the third sub duration S3. The first and second power levels are the ON state, and the third power level is the OFF state. The first power level is greater than the second power level. The third power level is a zero power level. The second RF pulse signal has a fourth power level in the first sub duration S1, and a fifth power level in the second and third sub durations S2 and S3. The fourth power level is the ON state, and the fifth power level is the OFF state. That is, the fifth power level is a zero power level. The third RF pulse signal has a sixth power level in the second sub duration S2, and a seventh power level in the first and third sub durations S1 and S3. The sixth power level is the ON state, and the seventh power level is

the OFF state. That is, the seventh power level is a zero power level. Thus, the first RF pulse signal HF has three or more different power levels (e.g. High/Low/OFF) in each of the plurality of first sub cycles (Sub cycles 1) and the plurality of second sub cycles (Sub cycles 2). The plurality of first sub cycles are included in the first duration M1. The plurality of second sub cycles are included in the second duration M2. Each first sub cycle has a first time duration, and each second sub cycle has a second time duration. In an embodiment, the first time duration is the same as the second time duration. In this case, each main cycle includes a plurality of sub cycles (Sub cycles 1+Sub cycles 2). The first RF pulse signal HF has a first pulse pattern in each of the plurality of first sub cycles, and a second pulse pattern in each of the plurality of second sub cycles. In an embodiment, the first pulse pattern is the same as the second pulse pattern. Further, the second RF pulse signal LF1 has two or more different power levels (e.g., ON/OFF) in each of the plurality of first sub cycles of the first duration M1 , and a zero power level in the second duration M2. That is, the second RF pulse signal LF1 is maintained at a zero power level in the second duration M2. Further, the third RF pulse signal LF2 has two or more different power levels (e.g., ON/OFF) in each of the plurality of first sub cycles of the first duration M1 , and has a zero power level in the second duration M2. That is, the third RF pulse signal LF2 is maintained at a zero power level in the second duration M2.

In an embodiment, the plasma processing method includes the following steps in each first sub cycle of the first duration M1. The first RF pulse signal HF having three or more different power levels (e.g., High/Low/OFF) is periodically supplied to the antenna 14. The second RF pulse signal LF1 having two or more different power levels (e.g., ON/OFF) is periodically supplied to the lower electrode in the substrate support 11. The third RF pulse signal LF2 having two or more different power levels (e.g., ON/OFF) is periodically supplied to the lower electrode in the substrate support 11. Further, the plasma processing method includes the following steps in the second duration M2. Without supplying the second and third RF pulse signals LF1 and LF2 to the lower electrode in the substrate support 11, the first RF pulse signal LF1 is periodically supplied to the antenna 14.

In the first sub duration S1 of FIG. 15, the HF power has the High power level, the LF1 power is at the ON state, and the LF2 power is at the OFF state. That is, during the time from a timing t0 to a timing t11, a plasma containing radicals and ions is generated by the supply of the HF power. Further, during the time from the timing t0 to the timing t11, the flux of ions (the amount of ions) reaching the bottom of a recess being etched may be controlled, so that the etching may be accelerated. Thus, as illustrated in FIG. 16A, the etching target film 200 is etched through the mask 201, and radicals R adhere mainly to the inner wall of a recess 200b formed in the etching target film 200. Further, ions are controlled, thereby controlling the flux of ions reaching the bottom of the etched recess 200b.

Further, the first sub duration S1 is set to a time of 30 μs or less. The subsequent second and third sub durations S2 and S3 are set to arbitrary times, which may be longer than 30 μs. That is, in this example, the HF power and the LF1 power are maintained at the ON state for the time of 30 μs or less in the first sub duration S1. In this way, the LF1 power is supplied for the short time of 30 μs or less in the first sub duration S1, so that the ion incidence angle may be controlled to be further vertical, which may implement the highly anisotropic etching.

At the timing t11 after the first sub duration S1 elapses, the HF power transitions from the High power level to the Low power level (or the OFF state), the LF1 power transitions to the OFF state, and the LF2 power transitions to the ON state. Then, the radicals, ions, and electron temperature decline with their respective time constants as in the example illustrated in FIG. 3. Depending on the decline state of the plasma parameters, it is possible to control the timing for turning ON the LF2 power in the second sub duration S2 when the power level of the HF power is lowered or controlled to the OFF state, and in the third sub duration S3 when by-products are exhausted.

In the second sub duration S2, the HF power is maintained at the Low power level, the LF1 power is maintained at the OFF state, and the LF2 power is maintained at the ON state. In the second sub duration S2, the LF2 power is supplied at a lower frequency than the frequency of the LF1 power supplied in the first sub duration S1. Vpp of the LF2 power is greater than Vpp of the LF1 power. Thus, in the second sub duration S2, Vpp of the bias voltage may become greater than in the first sub duration S1, so that the ion energy may be further increased, and thus, the ion incidence angle may be controlled to be further vertical. As a result, as illustrated in FIG. 16B, the flux of ions reaching the bottom of the etched recess 200b in the second sub duration S2 may be controlled. Then, for example, by-products B remaining in the corners of the bottom of the recess 200b are etched, so that the etching may be accelerated.

At a timing t12, the HF power transitions to the OFF state (or the Low power level), the LF1 power is maintained at the OFF state, and the LF2 power transitions to the OFF state. In the third sub duration S3, the exhaust of by-products B is controlled. That is, in the third sub duration S3, the HF power, the LF1 power, and the LF2 power are maintained at the OFF state. Thus, the by-products B adhered in the recess 200b are exhausted. As a result, the etching in the subsequent cycle may be accelerated.

At a timing t13, the first sub duration S1 begins again, the HF power transitions to the High power level, the LF1 power transitions to the ON state, and the LF2 power is maintained at the OFF state. The first to third sub durations S1 to S3 are repeated, and one period of the first sub cycle is 1 kHz to 20 kHz. The plurality of first sub cycles have the same time duration, and each first sub cycle is 50 μs to 100 μs. That is, one period of the first sub cycle is 50 μs to 100 μs.

In this way, in the first duration M1, when performing the process of etching a deep hole with a high aspect ratio, the mask selectivity may be increased, and the ion incidence angle may be controlled to be vertical, by using the pulse signals of the HF power, the LF1 power, and the LF2 power. Accordingly, the etching shape may be made vertical, and the etching may be accelerated.

Subsequently, in each second sub cycle of the second duration M2, the pulse signal of the HF power is controlled in the same manner as in the first duration M1. Meanwhile, in each second sub cycle, the LF1 power and the LF2 power are not supplied in any of the first to third sub durations S1 to S3. That is, the power levels of the LF1 power pulse signal (e.g., the second RF pulse signal) and the LF2 power pulse signal (e.g., the third RF pulse signal) are a zero power level. In this case, since the LF1 power and the LF2 power are at the OFF state in the second duration M2, by-products are exhausted. Further, the second duration M2 is preset to a time, which is sufficiently long and prevents by-products from adhering to the substrate W.

In the third embodiment, the power level of the HF power is controlled at three levels, and the power levels of the LF1 power and the LF2 power are controlled at the two levels of ON/OFF states. However, the present disclosure is not limited thereto. For example, the power level of the HF power may be controlled at four or more levels.

### Fourth Embodiment

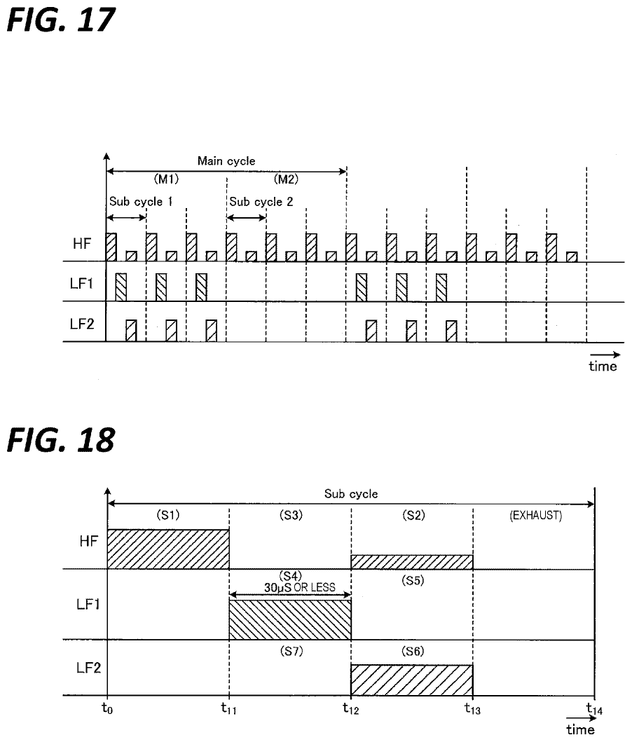

FIG. 17 is a view illustrating pulse patterns of three-frequency RF power pulses according to a fourth embodiment. FIG. 18 is a view illustrating the pulse patterns of the three-frequency RF power pulses in one period of a sub cycle according to the fourth embodiment. In FIGS. 17 and 18, the horizontal axis represents time, and the vertical axis represents the ON/OFF states of the HF power, the LF1 power, and the LF2 power.

As illustrated in FIG. 17, in the fourth embodiment, the main cycle includes a first duration M1 including a plurality of first sub cycles and a second duration M2 including a plurality of second sub cycles as in the third embodiment. One period of the main cycle is 10 Hz to 200 Hz. As illustrated in FIG. 18, each sub cycle of the HF power (e.g., each of the first and second sub cycles) includes first to third sub durations S1 to S3. Each first sub cycle of the LF1 power in the first duration M1 includes fourth and fifth sub durations S4 and S5. Each first sub cycle of the LF2 power in the first duration M1 includes sixth and seventh sub durations S6 and S7. In each second sub cycle of the second duration M2, the LF1 power and the LF2 power are not supplied. One cycle of each of the first and second sub cycles is 1 kHz to 20 kHz. Then, the control of the pulse signal of each of the HF power, the LF1 power, and the LF2 power is repeated with the main cycle as one period.

The first RF generator 31a is configured to generate a first RF pulse signal (e.g., the HF power), and in the fourth embodiment, the first RF pulse signal has three power levels (e.g., High/Low/OFF). These power levels may be set and changed arbitrarily according to a target process. For example, the first RF pulse signal may have a frequency of 27 MHz.

The second RF generator 31b is configured to generate a second RF pulse signal (e.g., the LF1 power), and in the fourth embodiment, the second RF pulse signal has two power levels (e.g., ON/OFF). That is, the second RF pulse signal has two or more power levels including a zero power level. The frequency of the second RF pulse signal is less than the frequency of the first RF pulse signal. For example, the second RF pulse signal has a frequency of 13 MHz.

The third RF generator 31c is configured to generate a third RF pulse signal (e.g., the LF2 power), and in the fourth embodiment, the third RF pulse signal has two power levels (e.g., ON/OFF). That is, the third RF pulse signal has two or more power levels including a zero power level. The frequency of the third RF pulse signal is less than the frequency of the second RF pulse signal. For example, the third RF pulse signal has a frequency of 1.2 MHz.

In each first sub cycle of the first duration M1, the ON state of the LF1 power and the ON state of the LF2 power do not overlap with each other in time as illustrated in FIG. 18. While the LF1 power is at the ON state, the LF2 power is at the OFF state, and while the LF1 power is at the OFF state, the LF2 power is at the ON state. Further, the High power level of the HF power and the ON state of the LF1 power do not overlap with each other in time. While the HF power is at the High power level, the LF1 power is at the OFF state, while the LF1 power is at the ON state, the HF power is at the OFF state or the Low power level. Similarly, the High power level of the HF power and the ON state of the LF2 power do not overlap with each other in time. While the HF power is at the High power level, the LF2 power is at the OFF state, and while the LF2 power is at the ON state, the HF power is at the OFF state or the Low power level.

For example, the first RF pulse signal has a first power level in the first sub duration S1, a second power level in the second sub duration S2, and a third power level in the third sub duration S3. The first and second power levels are the ON state, and the third power level is the OFF state. The first power level is greater than the second power level. The second power level is greater than the third power level, and the third power level is a zero power level. The second RF pulse signal has a fourth power level in the fourth sub duration S4, and a fifth power level in the fifth sub duration S5. The fourth power level is the ON state, and the fifth power level is the OFF state. That is, the fifth power level is a zero power level. The third RF pulse signal has a sixth power level in the sixth sub duration S6, and a seventh power level in the seventh sub duration S7. The sixth power level is the ON state, and the seventh power level is the OFF state. That is, the seventh power level is a zero power level.

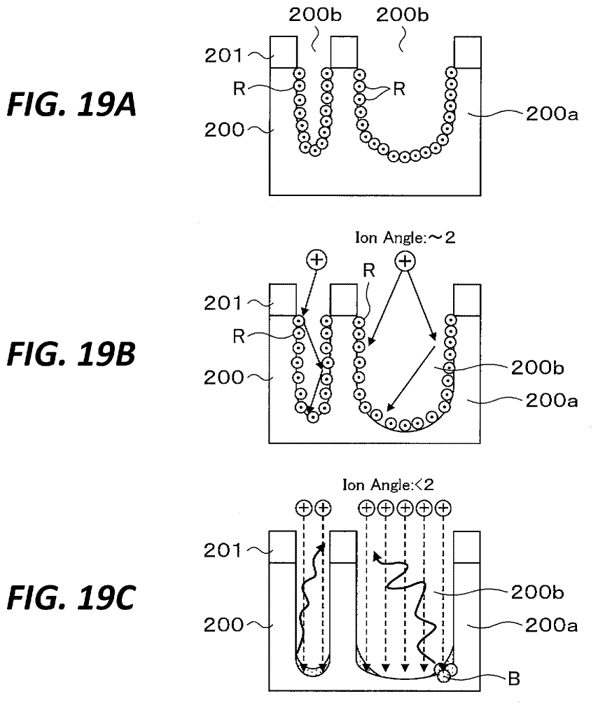

In the first sub duration S1 of FIG. 18, the HF power has the High power level, and the LF1 power and the LF2 power are at the OFF state. That is, during the time from a timing t0 to a timing t11, a plasma containing radicals and ions is generated by the supply of the HF power. Thus, as illustrated in FIG. 19A, the etching target film 200 is etched through the mask 201, and radicals R adhere mainly to the inner wall of the recess 200b formed in the etching target film 200.

When the HF power transitions to the OFF state at the timing t11 after the first sub duration S1 elapses, the radicals, ions, and electron temperature decline with their respective time constants as in the example illustrated in FIG. 3. Depending on the decline state of the plasma parameters, it is possible to control the timing for turning ON each of the LF1 power and the LF2 power in the third sub duration S2 when the HF power is at the OFF state, in the second sub duration S2 when the power level of the HF power is lowered, and in the duration when by-products are exhausted. At this time, the fourth sub duration S4 when the LF1 power is at the ON state does not overlap in time with the first sub duration S1 when the HF power is at the High power level. Further, the sixth sub duration S6 when the LF2 power is at the ON state does not overlap in time with the first and fourth sub durations S1 and S4.

At the timing t11, the HF power transitions from the High power level to the OFF state, and the LF1 power transitions to the ON state. Thus, in the fourth sub duration S4 overlapping in time with the third sub duration S3, the LF1 power is maintained at the ON state, and the flux of ions reaching the bottom of the etched recess 200b may be controlled as illustrated in FIG. 19B. Further, the amount of by-products may be suppressed during the etching. The LF2 power is maintained at the OFF state at the timing t11, and still maintained at the OFF state in the seventh sub duration S7 coincident in time with the third sub duration S3.

The fourth sub duration S4 is set to a time of 30 μs or less. Further, the fourth sub duration S4 does not overlap in time with the first sub duration S1. The LF1 power is supplied for the short time of 30 μs or less in the fourth sub duration S4, so that the ion incidence angle may be controlled to be further vertical, which may implement the highly anisotropic etching.

At a timing t12 after the third and fourth sub durations S3 and S4 elapse, the HF power transitions to the Low power level, the LF1 power transitions to the OFF state, and the LF2 power transitions to the ON state. In the second sub duration S2 until a timing t13, the HF power is maintained at the Low power level. In the third sub duration S3 and the second sub duration S2, the HF power may be at the Low power level or at the OFF state. In the fifth sub duration S5 coincident in time with the second sub duration S2, the LF1 power is maintained at the OFF state, and in the sixth sub duration S6 coincident in time with the second sub duration S2, the LF2 power is maintained at the ON state. As described above, the sixth sub duration S6 does not overlap in time with the first and fourth sub durations S1 and S4.

In the sixth sub duration S6, the LF2 power with a lower frequency than the frequency of the LF1 power supplied in the fourth sub duration S4 is supplied. Vpp of the LF2 power is greater than Vpp of the LF1 power. Thus, in the sixth sub duration S6, Vpp of the bias voltage may become greater than in the fourth sub duration S4, so that the ion energy may be further increased, and thus, the ion incidence angle may be controlled to be further vertical. As a result, as illustrated in FIG. 19C, the flux of ions reaching the bottom of the etched recess 200b may be controlled in the sixth sub duration S6 when the LF2 power is supplied. Then, for example, the by-products B remaining in the corners of the bottom of the recess 200b are etched, so that the etching may be accelerated.

At a timing t14, one period ends, and the first sub duration Si of the next period begins. Then, at the timing t0 of the next period, the HF power transitions to the High power level, and the LF1 power and the LF2 power are maintained at the OFF state. The HF power of the first RF pulse signal is brought into a predetermined state in an order of the first sub duration S1→the third sub duration S3→the second sub duration S2→the exhaust duration. The LF1 power of the second RF pulse signal is brought into a predetermined state in an order of the fourth sub duration S4→the fifth sub duration S3→the exhaust duration. The LF2 power of the third RF pulse signal is brought into a predetermined state in an order of the seventh sub duration S7→the sixth sub duration S6→the exhaust duration. Each first sub cycle is repeated, and one period thereof is 1 kHz to 20 kHz. The plurality of first sub cycles have the same time duration, and each first sub cycle has a time duration of 50 μs to 1,000 μs. That is, one period of the first sub cycle is 50 μs to 1,000 μs.

In this way, in the first duration M1, when performing the process of etching a deep hole with a high aspect ratio, the mask selectivity may be increased, and the ion incidence angle may be controlled to be vertical, by using the pulse signals of the HF power, the LF1 power, and the LF2 power. Accordingly, the etching shape may be made vertical, and the etching may be accelerated.

Subsequently, in each second sub cycle of the second duration M2, the pulse signal of the HF power is controlled in the same manner as in the first duration M1. Meanwhile, the LF1 power and the LF2 power are not supplied in each second sub cycle. That is, the LF1 power pulse signal (e.g., the second RF pulse signal) and the LF2 power pulse signal (e.g., the third RF pulse signal) are a zero power level. In this case, since the LF1 power and the LF2 power are at the OFF state in the second duration M2, by-products are exhausted. Further, the second duration M2 is preset to a time, which is sufficiently long and prevents by-products from adhering to the substrate W.

In the fourth embodiment, the power level of the HF power is controlled at three levels, and the power levels of the LF1 power and the LF2 power are controlled at the two levels of ON/OFF states. However, the present disclosure is not limited thereto. For example, the power level of the HF power may be controlled at four or more levels.

### Modifications of Fourth Embodiment

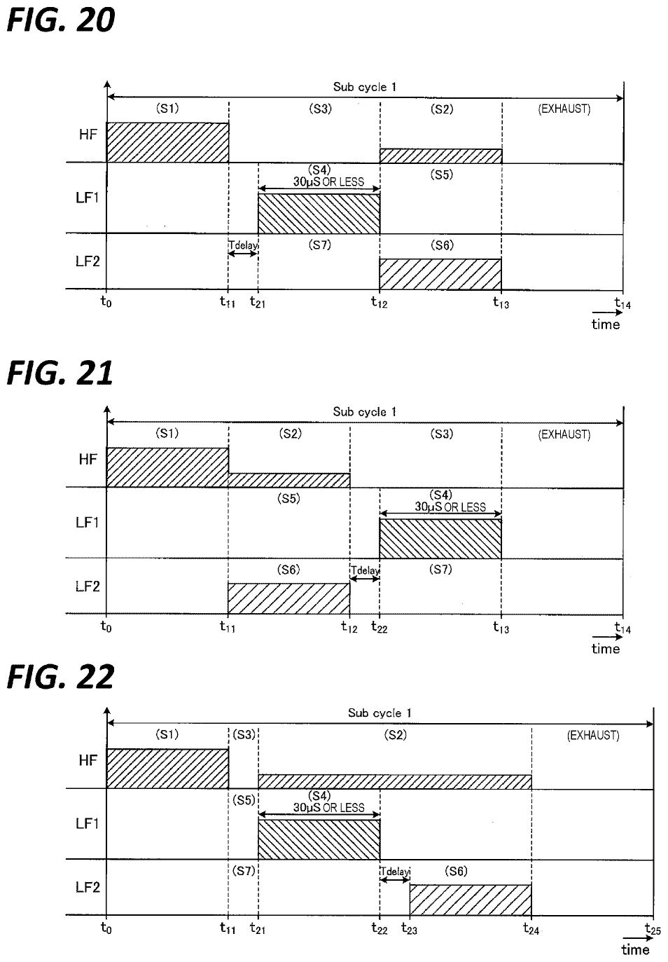

Next, modifications of the fourth embodiment will be described. The present modifications are modifications to the pulse patterns of the three-frequency RF power pulses in each first sub cycle of the first duration M1 in the fourth embodiment. FIGS. 20 to 22 are views illustrating pulse patterns of three-frequency RF power pulses in one period of a first sub cycle according to the modifications of the fourth embodiment.

The modification illustrated in FIG. 20 is described below.

The pulse patterns illustrated in FIG. 18 and the pulse patterns illustrated in FIG. 20 are different in that FIG. 20 includes a delay time Tdelay after the end timing t11 of the first sub duration S1, whereas FIG. 18 has no delay time Tdelay after the timing t11. Hereinafter, this difference will be described, and since the other pulse patterns of FIG. 20 are the same as those in FIG. 18, descriptions thereof will be omitted.

For example, as illustrated in FIG. 3, when the LF1 or LF2 power is turned ON in a state where the electron temperature is high, more by-products are generated, which may hinder the etching. Thus, it may be considered to turn ON the LF1 or LF2 power avoiding the time when the electron temperature is high. That is, at a timing t21 after a predetermined delay time Tdelay elapses from the timing t11, the electron temperature declines. At this timing, the LF1 power transitions to the ON state. That is, the LF1 power transitions to the ON state after the elapse of time (delay) by the delay time Tdelay from the timing t11 when the HF power transitions to the OFF state. Thus, the amount of by-products during the etching may be suppressed, and the etching may be accelerated.

Further, in the present modification, the HF power is at the OFF state during the delay time Tdelay. However, the power level of the HF power during the delay time Tdelay may be the Low level less than the power level of the HF power in the first sub duration S1. By lowering the power level of the HF power, the generation of radicals and ions may be reduced during the delay time Tdelay before the timing t21 when the LF1 power is supplied. As a result, the flux of ions reaching the bottom of a recess formed in the etching target film may be controlled in the fourth sub duration S4 from the timing t21 to the timing t12 after the elapse of the delay time Tdelay. The fourth sub duration S4 is set to a time of 30 μs or less. Further, the fourth sub duration S4 does not overlap in time with the first sub duration S1. The subsequent fifth sub duration S5 and exhaust duration are set to arbitrary times, which may be longer than 30 μs. In this way, the LF1 power is supplied for the short time of 30 μs or less in the fourth sub duration S4, so that the ion incidence angle may be controlled to be further vertical, which may implement the highly anisotropic etching.

At the timing t12, the LF1 power transitions to the OFF state, and the LF2 power transitions to the ON state. In the fifth sub duration S5, the LF1 power transitions to the OFF state, and in the sixth sub duration S6 overlapping in time with the fifth sub duration S5, the LF2 power transitions to the ON state. Thus, in the sixth sub duration S6, the ion incidence angle may be controlled to be further vertical, as compared to the fourth sub duration S4. However, when the delay time Tdelay is excessively long, ions may be lost. Thus, the delay time Tdelay is set in advance to an appropriate value.

Through this control, the ON/OFF states of the LF1 power and the ON/OFF states of the LF2 power transition to the ON state at different times, thereby controlling mainly the behavior of ions. The HF power has a zero power level in the third sub duration S3, the LF1 power has a power level greater than zero in the fourth sub duration S4, and the LF2 power has a zero power level in the seventh sub duration S7 overlapping with the fourth sub duration S4. The LF2 power has a power level greater than zero in the sixth sub duration S6, the LF1 power has a zero power level in the fifth sub duration S5 overlapping with the sixth sub duration S6, and the HF power has a power level greater than zero in the second sub duration S2. That is, the times when the LF1 power and the LF2 power have a power level greater than zero do not overlap with each other.

In the LF2 power, the mask selectivity is greater than that in the LF1 power, and the vertical etching is possible. In the first sub duration S1 when the power level of the HF power is greater than that in the second sub duration S2, radicals and ions are generated in large amounts, and the effects above may not be achieved even when the LF2 power is supplied during the first sub duration S1. Meanwhile, in the second sub duration S2 when the power level of the HF power is less than that in the first sub duration S1 and in the third sub duration S3 when the HF power is a zero power level, the generation of radicals and ions decreases. Thus, the effects above may easily be achieved by supplying the LF1 power in the fourth sub duration S4 overlapping with the third sub duration S3, and supplying the LF2 power in the sixth sub duration S6 overlapping with the second sub duration S2. By supplying the LF1 or LF2 power during these durations, the ion energy may be increased, so that the ion incidence angle may become vertical. As a result, in the second and third sub durations S2 and S3, the mask selectivity is greater than that in the first sub duration S1, and the vertical etching is possible.

The LF1 power and the LF2 power may generate pulse signals having the two power levels of the ON and OFF states. However, the LF1 power and the LF2 power may generate pulse signals having two or more power levels such as the ON state, the OFF state, and an intermediate power level. The LF1 power and the LF2 power may have two different ON states.

The modification illustrated in FIG. 21 is described below.

The pulse patterns of FIG. 21 are different from the pulse patterns of FIG. 20 in that in FIG. 21, the order of the ON state of the LF1 power and the ON state of the LF2 power are reversed, and the timing of the delay time Tdelay transitions accordingly. The delay time Tdelay is provided immediately before the LF1 power transitions to the ON state.

In the present modification as well, the LF1 or LF2 power is turned ON avoiding the time when the electron temperature is high. In the present modification, the LF2 power and the LF1 power are turned ON in this order. At a timing t11 after the first sub duration S1 elapses, the electron temperature declines. At this timing, that is, at the timing t11 when the HF power transitions to the Low power level less than the High power level, the LF2 power transitions to the ON state and is maintained at the ON state in the sixth sub duration S6 coincident in time with the second sub duration S2. Thus, the amount of by-products during the etching may be suppressed, and the etching may be accelerated.

The LF1 power is maintained at the OFF state in the fifth sub duration S5 from the timing t11 to a timing t12 coincident in time with the second sub duration S2. In the present modification, the HF power transitions to the OFF state at the timing t12, the LF1 power is maintains at the OFF state, and the LF2 power transitions to the OFF state. During the delay time Tdelay, the HF power is maintained at the OFF state. However, the power level of the HF power during the delay time Tdelay may be the Low level less than the power level of the HF power in the first sub duration S1. By further lowering the power level of the HF power, the generation of radicals and ions may be reduced during the delay time Tdelay before a timing t22 when the LF1 power is supplied.

At the timing t22 after the delay time Tdelay elapses from the timing t12, the LF1 power transitions to the ON state. At the timing t22, the HF power and the LF2 power are maintained at the OFF state. As a result, the flux of ions reaching the bottom of a recess formed in the etching target film may be controlled in the fourth sub duration S4 from the timing t22 to a timing t13 after the elapse of the delay time Tdelay. At this time, the fourth sub duration S4 is set to a time of 30 μs or less. Further, the fourth sub duration S4 does not overlap in time with the first sub duration S1. The fifth sub duration S5 coincident in time with the second sub duration S2, and the exhaust duration are set to arbitrary times, which may be longer than 30 μs. That is, in the present modification, the LF1 power is maintained at the ON state for the time of 30 μs or less in the first sub duration S4. In this way, the LF1 power is supplied for the short time of 30 μs or less in the fourth sub duration S4, so that the ion incidence angle may be controlled to be further vertical, which may implement the highly anisotropic etching. However, when the delay time Tdelay is excessively long, ions may be lost. Thus, the delay time Tdelay is set in advance to an appropriate value.

The modification illustrated in FIG. 22 is described below.

The pulse patterns of FIG. 22 are different from the pulse patterns of FIGS. 20 and 21 in that the delay time Tdelay in FIGS. 20 and 21 is provided immediately before the LF1 power transitions to the ON state, whereas the delay time Tdelay in FIG. 22 is provided immediately before the LF2 power transitions to the ON state.

In the present modification, in the first sub duration S1, the HF power is maintained at the High power level, and the LF1 power and the LF2 power are maintained at the OFF state. In the third sub duration S3, and the fifth and seventh sub durations S5 and S7 coincident in time with the third sub duration S3, the HF power, the LF1 power, and the LF2 power are all maintained at the OFF state (exhaust duration).

Then, at a timing t21, the HF power transitions to the Low power level less than the High power level, and the LF1 power transitions to the ON state. At the timing t21, the LF2 power is maintained at the OFF state. Then, in the second sub duration S2, the HF power is maintained at the Low power level. The fourth sub duration S4 overlaps in time with the second sub duration S2. That is, in the fourth sub duration S4 coincident in time with a portion of the second sub duration S2, the LF1 power is maintained at the ON state for a time of 30 μs or less. The LF1 power transitions to the OFF state at a timing t22 in the second sub duration S2, and the LF2 power transitions to the ON state at a timing t23 after the elapse of the delay time Tdelay from the timing t22. At the timings t22 and t23, the HF power is maintained at the Low power level. Then, the LF2 power is maintained at the ON state in the sixth sub duration S6, from the timing t23, overlapping in time with the second sub duration S2 (e.g. coincident in time with a portion of the second sub duration S2).

In the present modification, the LF1 power and the LF2 power are alternately turned ON in the second sub duration S2 when the HF power is maintained at the Low power level. Further, the LF1 power is supplied for the short time of 30 μs or less in the fourth sub duration S4. As a result, the ion incidence angle may be controlled to be further vertical, which may implement the highly anisotropic etching. Since the control for the exhaust duration from a timing t24 after the elapse of the sixth sub duration S6 to a timing t25 is the same as the control for the other first sub cycles, descriptions thereof are omitted herein. As described above, according to the plasma processing apparatus and the plasma processing method of the present embodiment, the process performance may be improved using a plurality of RF power pulse signals.

The embodiments disclosed herein are merely examples in all aspects, and should not be construed as being limited. The foregoing embodiments may be omitted, substituted, or modified in various forms without departing from the scope and gist described in the accompanying claims.

For example, in the embodiments above, for example, the inductively coupled plasma apparatus has been described. However, the present disclosure may be applied to other plasma apparatuses. For example, a capacitively coupled plasma apparatus may be used, instead of the inductively coupled plasma apparatus. In this case, the capacitively coupled plasma apparatus includes an upper electrode and a lower electrode. The lower electrode is disposed inside the substrate support, and the upper electrode is disposed above the substrate support. The first RF generator 31a is coupled to the upper or lower electrode, and the second and third RF generators 31b and 31c are coupled to the lower electrode. Thus, the first RF generator 31a is coupled to the antenna 14 of the inductively coupled plasma apparatus or the upper electrode of the capacitively coupled plasma apparatus. That is, the first RF generator 31a is coupled to a plasma processing chamber.

According to the present disclosure, the process performance may be improved using a plurality of radio-frequency power pulse signals.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a plasma processing chamber;
a substrate support disposed in the plasma processing chamber;
an electrode disposed in the substrate support;
a first RF generator coupled to the plasma processing chamber, and configured to generate a first RF pulse signal including a plurality of main cycles, each main cycle including a first duration and a second duration, the first duration including a plurality of first sub cycles, the second duration including a plurality of second sub cycles, the first RF pulse signal having three or more different power levels in each of the plurality of first sub cycles and the plurality of second sub cycles;
a second RF generator coupled to the electrode, and configured to generate a second RF pulse signal including the plurality of main cycles, the second RF pulse signal having two or more different power levels in each of the plurality of first sub cycles and a zero power level in the second duration; and
a third RF generator coupled to the electrode, and configured to generate a third RF pulse signal including the plurality of main cycles, the third RF pulse signal having two or more different power levels in each of the plurality of first sub cycles and a zero power level in the second duration.

2. The plasma processing apparatus according to claim 1, wherein the first RF pulse signal has a first frequency,
the second RF pulse signal has a second frequency less than the first frequency, and
the third RF pulse signal has a third frequency less than the second frequency.

3. The plasma processing apparatus according to claim 1, wherein the first RF pulse signal has a first power level, a second power level, and a third power level,
the second RF pulse signal has a fourth power level and a fifth power level,
the third RF pulse signal has a sixth power level and a seventh power level,
a duration of the fourth power level coincides with a duration of the first power level, and
a duration of the sixth power level coincides with a duration of the second power level.

4. The plasma processing apparatus according to claim 3, wherein a duration of the fifth power level coincides with the duration of the second power level, and
a duration of the seventh power level coincides with the duration of the first power level.

5. The plasma processing apparatus according to claim 3, wherein the third power level, the fifth power level, and the seventh power level are a zero power level.

6. The plasma processing apparatus according to claim 3, wherein the first power level is greater than the second power level.

7. The plasma processing apparatus according to claim 3, wherein the duration of the first power level is equal to or less than 30 μs.

8. The plasma processing apparatus according to claim 1, wherein the first RF pulse signal has a first power level, a second power level, and a third power level,
the second RF pulse signal has a fourth power level and a fifth power level,
the third RF pulse signal has a sixth power level and a seventh power level,
a duration of the fourth power level does not overlap with a duration of the first power level.
a duration of the sixth power level does not overlap with the duration of the first power level, and
the duration of the sixth power level does not overlap with the duration of the fourth power level.

9. The plasma processing apparatus according to claim 8, wherein the third power level, the fifth power level, and the seventh power level are a zero power level.

10. The plasma processing apparatus according to claim 8, wherein the first power level is greater than the second power level,
the second power level is greater than the third power level,
the duration of the fourth power level overlaps with a duration of the third power level, and
the duration of the sixth power level overlaps with a duration of the second power level.

11. The plasma processing apparatus according to claim 10, wherein the third power level transitions from the first power level, and the second power level transitions from the third power level,
the duration of the fourth power level coincides with the duration of the third power level, and
the duration of the sixth power level coincides with the duration of the second power level.

12. The plasma processing apparatus according to claim 10, wherein the third power level transitions from the first power level, and the second power level transitions from the third power level,
the fourth power level begins after a predetermined time elapses from the transition from the first power level to the third power level, and ends simultaneously with the transition from the third power level to the second power level, and
the duration of the sixth power level coincides with the duration of the second power level.

13. The plasma processing apparatus according to claim 10, wherein the second power level transitions from the first power level, and the third power level transitions from the second power level,
the fourth power level begins after a predetermined time elapses from the transition from the second power level to the third power level, and ends simultaneously with an end of the third power level, and
the duration of the sixth power level coincides with the duration of the second power level.

14. The plasma processing apparatus according to claim 8, wherein the first power level is greater than the second power level,
the second power level is greater than the third power level,
the duration of the fourth power level overlaps with the duration of the second power level, and
the duration of the sixth power level overlaps with the duration of the second power level.

15. The plasma processing apparatus according to claim 14, wherein the third power level transitions from the first power level, and the second power level transitions from the third power level,
the fourth power level begins simultaneously with the transition from the third power level to the second power level, and ends before an end of the second power level, and
the sixth power level begins simultaneously with an end of the fourth power level or after a predetermined time elapses from the end of the fourth power level, and ends before the end of the second power level.

16. The plasma processing apparatus according to claim 8, wherein the duration of the fourth power level is equal to or less than 30 μs.

17. The plasma processing apparatus according to claim 1, wherein one period of the main cycle is 10 Hz to 200 Hz, and
one period of each of the plurality of first sub cycles and the plurality of second sub cycles is 1 kHz to 20 kHz.

18. A plasma processing apparatus comprising:
a plasma processing chamber;
a substrate support disposed in the plasma processing chamber;
an electrode disposed in the substrate support;
a first RF generator coupled to the plasma processing chamber, and configured to generate a first RF pulse signal including a plurality of main cycles, each main cycle including a first duration and a second duration, the first duration including a plurality of first sub cycles, the second duration including a plurality of second sub cycles, the first RF pulse signal having two or more different power levels in each of the plurality of first sub cycles and the plurality of second sub cycles; and
a second RF generator coupled to the electrode, and configured to generate a second RF pulse signal including the plurality of main cycles, the second RF pulse signal having two or more different power levels in each of the plurality of first sub cycles and a zero power level in the second duration.

19. The plasma processing apparatus according to claim 18, wherein the first RF pulse signal has a first frequency, and
the second RF pulse signal has a second frequency less than the first frequency.

20. The plasma processing apparatus according to claim 18, wherein the first RF pulse signal has a first power level and a second power level,
the second RF pulse signal has a third power level and a fourth power level, and
a duration of the third power level coincides with a duration of the first power level.

21. The plasma processing apparatus according to claim 20, wherein the second power level and the fourth power level are a zero power level.

22. The plasma processing apparatus according to claim 20, wherein a duration of the first power level is equal to or less than 30 μs.

23. The plasma processing apparatus according to claim 18, wherein the first RF pulse signal has a first power level and a second power level,
the second RF pulse signal has a third power level and a fourth power level, and
a duration of the first power level does not overlap with a duration of the third power level.

24. The plasma processing apparatus according to claim 23, wherein the second power level and the fourth power level are a zero power level.

25. The plasma processing apparatus according to claim 23, wherein the duration of the third power level is equal to or less than 30 μs.

26. The plasma processing apparatus according to claim 18, wherein one period of the main cycle is 10 Hz to 200 Hz, and
one period of each of the plurality of first sub cycles and the plurality of second sub cycles is 1 kHz to 20 kHz.

27. A plasma processing method comprising:
providing a plasma processing apparatus including
a plasma processing chamber,
a substrate support disposed in the plasma processing chamber,
an electrode disposed in the substrate support, and
an antenna disposed above the substrate support,
generating a first RF pulse signal, a second RF pulse signal, and a third RF pulse signal, each including a plurality of main cycles, each main cycle including a first duration and a second duration, wherein the first duration includes a plurality of first sub cycles,
in each of the plurality of first sub cycles,
periodically supplying the first RF pulse signal having three or more different power levels to the antenna,
periodically supplying the second RF pulse signal having two or more different power levels to the electrode, and
periodically supplying the third RF pulse signal having two or more different power levels to the electrode,
in the second duration,
periodically supplying the first RF pulse signal to the antenna, without supplying the second RF pulse signal and the third RF pulse signal to the electrode.
